(19) United States
(12) Patent Application Publication
(10) Pub. No.: US 2003/0044023 A1
(43) Pub. Date: Mar. 6, 2003

(54) Circuit and method for processing an audio signal

(76) Inventor: Erik Larsen, Urbana (IL)

Correspondence Address: Corporate Patent Counsel, U.S. Philips Corporation, 580 White Plains Road, Tarrytown, NY, 10591, US

(21) Appl. No.: 10/227,202

(22) Filed: Aug. 23, 2002

(30) Foreign Application Priority Data
Aug. 28, 2001 (EP) 01203248.8

(51) Int. Cl. H03G 3/00; H03G 5/00

(52) U.S. Cl. 381/61; 381/98

(57) ABSTRACT

The invention relates to a circuit (100) for processing an audio signal comprising first selection means (110) for selecting a frequency band (111) of the audio signal, a harmonic generator (120) arranged to generate sub-harmonics (231) of the frequencies (211) in the selected frequency band (111) and arranged to generate higher harmonics of the generated sub-harmonics (231). The circuit further comprises second selection means (130) for removing at least a part of the generated sub-harmonics (231) from the output signal of the harmonic generator (120). The circuit also comprises adding means (140) for adding the output signal of the second selection means (130) to the audio signal. This circuit can be used for bass enhancement of music. The invention further relates to a method of processing an audio signal, an apparatus (400) comprising a circuit (405) according to the invention and a record carrier (510) comprising instructions which can be carried out by a processor and enable it to perform the method according to the invention.

The invention relates to a circuit for processing an audio signal, the circuit comprising first selection means for selecting a frequency band of the audio signal, a harmonic generator adapted to generate sub-harmonics of frequencies in the selected frequency band and adapted to generate higher harmonics of the generated sub-harmonic, and adding means.

The invention also relates to an apparatus for reproducing audio signals, the apparatus comprising the circuit as defined in claim 1.

The invention further relates to a method of processing an audio signal, the method comprising the steps of selecting a frequency band of the audio signal and generating a signal comprising sub-harmonics of frequencies in the selected frequency band and higher harmonics of the generated sub-harmonics.

The invention also relates to a record carrier comprising instructions which can be carried out by a processor and enable the processor to perform the method as defined in claim 6.

An embodiment of such a circuit is known from EP 0 240 286.

This circuit has the drawback that the generated lower harmonics cannot be reproduced up to a given frequency by a small loudspeaker in, for example, portable sound systems. They may, however, damage the loudspeaker.

It is an object of the invention to prevent a loudspeaker connected to the circuit from being damaged.

According to the invention, this object is achieved in that the circuit further comprises second selection means which are adapted to remove at least a part of the generated sub-harmonics from the signal generated by the harmonic generator, and the adding means are adapted to add an output signal of the second selection means to the audio signal.

To give the user the impression that there are extra low frequencies in the sound signal, sub-harmonics of signal components having a low frequency are generated. However, these cannot be made audible with relatively small speakers. Nevertheless, to give the user the impression of hearing low tones, higher harmonics of the sub-harmonics are generated. However, the amplitudes of these higher harmonics should have a sufficient level. For this reason, the amplitude of the sub-harmonic will also have to be sufficiently high and may even be so high that the loudspeaker could be damaged if a signal having such a power were applied to the loudspeaker. It is therefore important to remove such a sub-harmonic, which is generated by the harmonic generator, from the signal generated by the harmonic generator.

An embodiment of the circuit according to the invention, in which an output of the adding means is connected to a loudspeaker, is characterized in that the second selection means are further adapted to remove low frequencies, which cannot be reproduced by the loudspeaker, from an output signal of the harmonic generator.

This has the advantage that the circuit is used as optimally as possible. The reason is that only frequency bands which are not reproduced are filtered from the signal generated by the harmonic generator.

An embodiment of the circuit according to the invention is characterized in that the second selection means comprise a filter which substantially does not pass at least a first frequency band and passes a second frequency band at a first level and a third frequency band at a second level.

This has the advantage that frequency bands generated by the harmonics can be amplified or attenuated with respect to each other. This leads to a better reproduction of the generated bass enhancement. The apparatus according to the invention is characterized in that it comprises a circuit as defined in claim 1.

The method according to the invention is characterized in that the method comprises the steps of removing at least a part of the sub-harmonics from the generated signal and adding the generated signal, from which at least a part of the sub-harmonics has been removed, to the audio signal.

The record carrier according to the invention is characterized in that the instructions enable the processor to perform the method defined in claim 6.

These and other aspects of the invention are apparent from and will be elucidated with reference to the embodiments described hereinafter.

In the drawings:

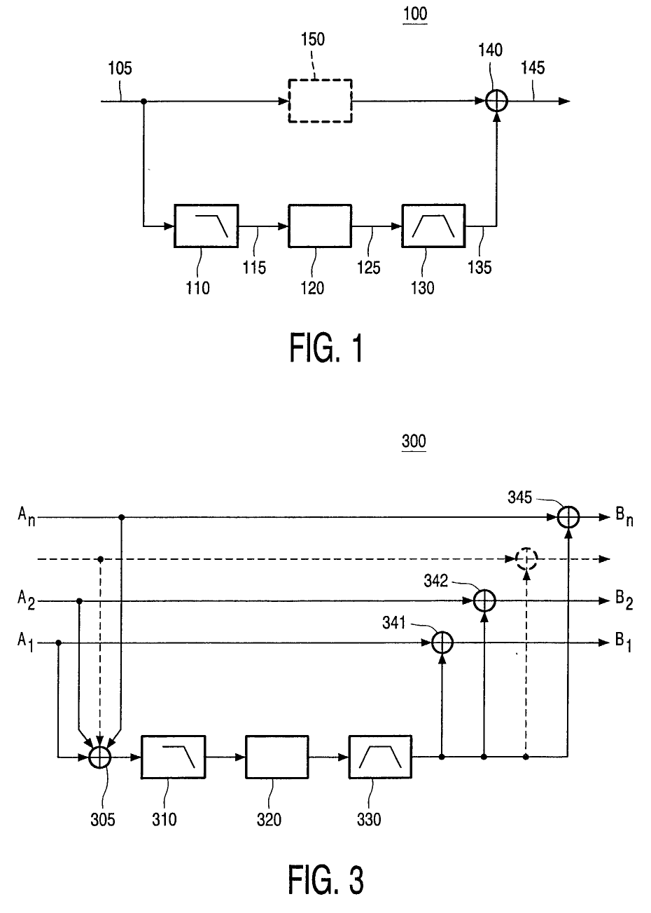

FIG. 1 shows an embodiment of a circuit according to the invention,

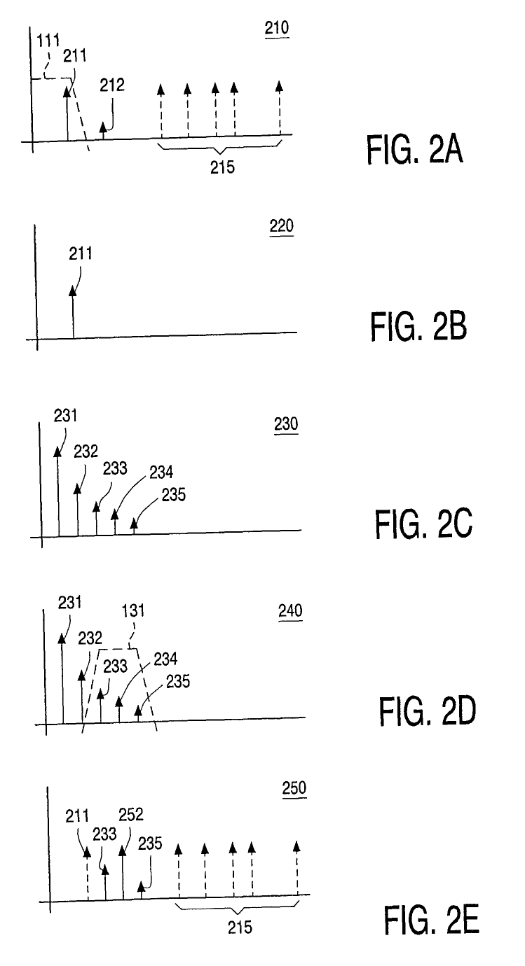

FIGS. 2A-2D show a number of frequency spectra to illustrate an embodiment of the method according to the invention,

FIG. 3 shows a circuit as a further embodiment of the invention,

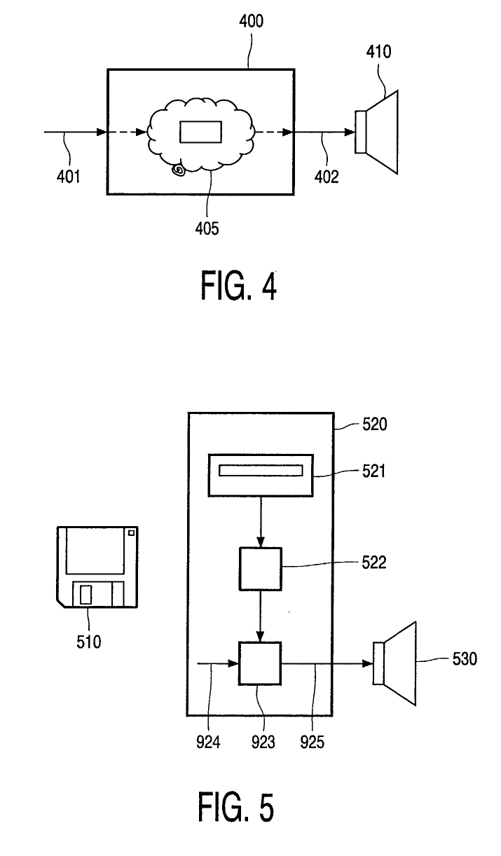

FIG. 4 shows an embodiment of the apparatus according to the invention and an embodiment of the record carrier comprising instructions which can be carried out by a processor according to the invention,

FIG. 5 shows an embodiment of the record carrier comprising instructions which can be carried out by a processor according to the invention, and a diagrammatical representation of a computer comprising the processor.

FIG. 1 shows a circuit 100 as an embodiment of the circuit according to the invention. The circuit 100 comprises a low-pass filter 110, a harmonic generator 120, a bandpass filter 130 and adding means 140. The operation of the circuit 100 will be explained with reference to FIGS. 2A through 2D.

An input 105 of the circuit 100 receives an input signal having a first frequency spectrum 210 as shown in FIG. 2A. The low-pass filter 110 having a low-pass characteristic 111 only passes a fundamental harmonic 211. A higher harmonic 212 of the fundamental harmonic 211 is not passed, likewise as a higher frequency spectrum 215.

FIG. 2B shows the frequency spectrum 220 of the signal which is applied by the low-pass filter 110 to the harmonic generator 120 via a first connection 115. The second frequency spectrum 220 comprises the fundamental harmonic 211.

The harmonic generator 120 generates a sub-harmonic 231 of the fundamental harmonic 211 at a frequency which is half the frequency of the fundamental harmonic 211 and a first higher harmonic 232, a second higher harmonic 233, a third higher harmonic 234 and a fourth higher harmonic 235, all of them being higher harmonics of the sub-harmonic 231. This is shown in a third frequency spectrum 230 in FIG. 2C. A plurality of higher harmonics may be generated, but for the sake of clarity, they are not shown in the third frequency spectrum 230. Those skilled in the art will already have noticed that the frequency of the first higher harmonic 232 of the sub-harmonic 231 is equal to the frequency of the fundamental harmonic 211. The sub-harmonic 231 and the higher harmonics are generated in a manner known to those skilled in the art, such as is known from, for example, U.S. Pat. No. 3,535,969. In the presented embodiment of the invention, the frequency of the sub-harmonic 231 is half the frequency of the fumdamental harmonic 211. In a further embodiment, the harmonic generator 120 generates a sub-harmonic at a frequency which is one-third, one-fourth or a smaller part of the frequency of the fundamental harmonic 211. This will be evident to those skilled in the art.

The signal which is generated by the harmonic generator 120 is applied to the bandpass filter 130 via a second connection 125. FIG. 2D shows the bandpass characteristic 131 of the bandpass filter 130. According to the invention, the bandpass characteristic 131 is determined in such a way that the bandpass filter 130 does not pass the generated sub-harmonic 231. In the presented embodiment of the invention, the bandpass filter 130 neither passes the first harmonic 332 of the generated sub-harmonic 231.

In the presented embodiment of the invention, the bandpass characteristic 131 has two kinks and the bandpass filter 130 is a passive filter. In a further embodiment of the invention, the bandpass filter 130 is an active filter and a bandpass characteristic of this filter may have one kink or more than two kinks and pass and/or block several frequency bands at different levels.

The signal, which is available at an output of the bandpass filter 130, is applied to the adding means 140 via a third connection 135. The adding means 140 are adapted to add the third interim signal to the input signal which is applied to the input 105 of the circuit 100. In this way, an output signal is created which is available for further use via an output 145. FIG. 2E shows the frequency spectrum 250 of the output signal of the circuit 100 which is available via the output 145. The frequency spectrum 250 shows the fundamental harmonic 211, the second higher harmonic 233, a summed harmonic 252 which is the sum of harmonic 234 and harmonic 212, the fourth higher harmonic 235 and the higher frequency spectrum 215. The summed harmonic 252 is the sum of the first higher harmonic 212 of the fundamental harmonic 211 and the third higher harmonic 234 of the sub-harmonic 231.

If the output signal of the circuit 100 is presented to a listener via a loudspeaker, it will sound to the listener as if a sound signal reproduced by the loudspeaker comprises a harmonic at the frequency of the sub-harmonic 231, in spite of the fact that this frequency is not present in the sound signal. The reason is that the listener does hear higher harmonics of the sub-harmonic 231. This has the advantage that, if the loudspeaker is so small that these signals or signal components at a low frequency cannot be reproduced, the method can give the user the impression that he is listening to more expensive loudspeakers which can reproduce the signals or signal components at a low frequency. This is a psycho-acoustical effect which is clearly described in literature. An example can be found in J. F. Schouten, “The perception of pitch” Philips Technical Review, 5 (10): 286, 1940. Furthermore, extra bass enhancement of a sound signal may be desirable if the sound signal comprises, for example, techno or gabber music.

To ensure that the listener gets the impression of hearing low tones while they are not there, it must be ensured that the amplitudes of the higher harmonics of the generated sub-harmonic are sufficiently large. This means that the sub-harmonic must have a considerable amplitude. Although the sub-harmonics generated by the harmonic generator 120 (FIG. 1) cannot always be reproduced through a small-format loudspeaker, the amplitude of the sub-harmonic may, however, sometimes be so high that it can damage this loudspeaker. To prevent this damage, the bandpass filter 130 (FIG. 1) in one embodiment of the invention is adapted in such a way that signals or signal components at a frequency which are not audible in a loudspeaker, connected to the circuit 100, are filtered by the bandpass filter 130 (FIG. 1) from the output signal of the harmonic generator 120. Even if the sub-harmonics that cannot be reproduced by the loudspeaker do not damage the loudspeaker, they will preferably still be filtered from the signal generated by the harmonic generator 120 because these sub-harmonics might lead to a distorted sound.

In the presented embodiment of the invention, the low-pass filter 110 is incorporated in the circuit 100. In a further preferred embodiment of the invention, this may also be a bandpass filter. The lower clipping frequency is then preferably between 30 Hz and 50 Hz. It has been proved that reproduction of frequency components at this frequency or at lower frequencies and reproduction of generated higher harmonics of these components are not pleasant to a listener.

In the presented embodiment of the invention, the bandpass filter 130 is incorporated in the circuit 100. In a further embodiment of the invention this may also be a high-pass filter. This does not depart from the scope of the invention as long as at least a part of the generated sub-harmonics is filtered from a signal generated by the harmonic generator 210.

If the bandpass filter 130 is an active filter, it may be formed with a passive filter in series with amplifier means (not shown). This embodiment is preferred. The amplification of the amplifier means is preferably controllable. The control may be realized by making the amplification dependent on the output signal.

In a preferred embodiment of the circuit according to the invention, the low-pass filter 110 and the bandpass filter 130 are linear phase filters.

The processing in the lower branch of the circuit 100 yields a delay of the signal. To ensure that the original signal in the upper branch of the circuit 100 has the same delay, the upper branch of the circuit in a further embodiment according to the invention incorporates an optional delay element 150. For those skilled in the art it is easy to compute the delay of the lower branch of the circuit 100. In a preferred embodiment of the invention, the delay in the upper branch of the circuit 100 is equal to the delay in the lower branch of the circuit 100.

It will be evident to those skilled in the art that the circuit according to the invention may be both digital and analog.

FIG. 3 shows a further circuit 300 as a further embodiment of the invention. The further circuit 300 comprises a low-pass filter 310, a harmonic generator 320 and a bandpass filter 330. The operation of these components is equal to the operation of the corresponding components of the circuit 100 shown in FIG. 1. The further circuit 300 also has a plurality of inputs denoted by A1, A2 and An, a plurality of outputs denoted by B1, B2 and Bn, and first adding means 305, second adding means 341, third adding means 342 and fourth adding means 345. The circuit 300 has the same function as the circuit 100. The difference between the circuit 300 and the circuit 100 is that the circuit 300 is suitable for processing signals from a plurality of sources. For example, the circuit 300 may be used in applications with stereo sound (two inputs, two outputs) or surround sound (five inputs, five outputs).

To this end, the signals from the inputs A1 . . . An are added by means of first adding means 305. The output signal of the first further adding means is subsequently processed by the further low-pass filter 310, the further harmonic generator 320 and the further bandpass filter 330 in accordance with the method described with reference to FIGS. 1 and 2. Subsequently, an output of the further bandpass filter 330 is coupled to the second further adding means 341, the third further adding means 342 and the fourth further adding means 345. The second further adding means 341, the third further adding means 342 and the fourth further adding means 345 add a signal, which is generated by the further bandpass filter 320, to signals at the inputs A1 . . . An. In this way, new signals are produced at the outputs denoted by B1, B2 and Bn. If the part of the signals selected by low-pass filter 310 at the inputs A1 . . . An does not comprise the same information for all signals, the processing of signals by means of the further circuit 300 may lead to crosstalk. However, this is not a great problem because low tones are difficult to localize. However, if crosstalk may be a problem, it will of course be evident to those skilled in the art to separately process all signals at the inputs A1 . . . An of the further circuit 300. This may be done with, for example, the circuit 100 (FIG. 1).

FIG. 4 shows an apparatus 400 for reproducing audio signals as an embodiment of the invention. The apparatus comprises input means 401, output means 402 and a circuit 405 as an embodiment of the invention. Possible embodiments of the input means may be RF antenna, SACD, DVD, CD, CD-ROM with, for example, MP3 files, tape cassettes, vinyl records or an electric or optical output signal of the apparatus 401, adapted to convert information on a record carrier into an optical or electric signal. However, this enumeration is not limitative, as will be evident to those skilled in the art. Possible embodiments of the output means are a CD burner, an electric signal or an RF signal. Also this enumeration is not limitative, as will be evident to those skilled in the art.

If the output means 402 represent an electric signal, they may be coupled to a loudspeaker 410. Those skilled in the art will understand that this may also be a group of loudspeakers if the apparatus 405 is, for example, a 5-channel surround sound system. If the loudspeaker 410 is relatively small because it is incorporated in, for example a portable apparatus, this loudspeaker will not be capable or hardly be capable of reproducing frequencies below 100 Hz-150 Hz. However, if these frequencies are present to a considerable extent in the electric signal supplied by the output means 402, they can damage the loudspeaker. It is therefore necessary to filter these frequency components from the signal supplied by the output means 402. If the circuit 405 in the apparatus 400 is equal to the circuit 100 (FIG. 1), this is possible by having the bandpass filter 130 (FIG. 1) filter these frequency components from the input signal of the harmonic generator 120 (FIG. 1) in order that they cannot damage the loudspeaker 410.

FIG. 5 shows a diskette 510 as an embodiment of a record carrier according to the invention, which diskette comprises instructions which can be carried out by a processor and enable the processor to perform the method according to the invention. The record carrier 510 may be used in a computer 520. This may be a personal computer but also, for example, a Personal Digital Assistant or a UNIX workstation. The computer 520 comprises a diskette station 521 which is connected to a processor 522. The processor 522 is further connected to a signal processing circuit 523 having an input 524 and an output 525. The diskette station 521 is adapted to read information from the diskette 510 and pass it on to the processor 522. The information comprises instructions which can be carried out by the processor 522 and enable the processor 522 to process, via the signal-processing circuit 523, an input signal at the input 524 of the signal-processing circuit 523 by means of the method according to the invention. The processed signal is subsequently passed on for the purpose of reproduction to a loudspeaker 530 via the output 525 of the signal processing circuit 523.

In the presented embodiment, the record carrier according to the invention is a diskette 510. However, the record carrier 510 may be alternatively a CD-ROM or a flash card but also a mass storage device which is coupled to a WAN such as the Internet. Another embodiment of the record carrier according to the invention is, however, also possible and does not depart from the scope of the invention.

In summary, the invention relates to a circuit (100) for processing an audio signal comprising first selection means (110) for selecting a frequency band (111) of the audio signal, a harmonic generator (120) arranged to generate sub-harmonics (231) of the frequencies (211) in the selected frequency band (111) and arranged to generate higher harmonics of the generated sub-harmonics (231). The circuit further comprises second selection means (130) for removing at least a part of the generated sub-harmonics (231) from the output signal of the harmonic generator (120). The circuit also comprises adding means (140) for adding the output signal of the second selection means (130) to the audio signal. This circuit can be used for bass enhancement of music. The invention further relates to a method of processing an audio signal, an apparatus (400) comprising a circuit (405) according to the invention and a record carrier (510) comprising instructions which can be carried out by a processor and enable it to perform the method according to the invention.

1. A circuit (100) for processing an audio signal, the circuit comprising
first selection means (110) for selecting a frequency band (111) of the audio signal,
a harmonic generator (120) adapted to generate sub-harmonics (231) of frequencies (211) in the selected frequency band (111) and adapted to generate higher harmonics (232) of the generated sub-harmonic (231), and
adding means (140),
characterized in that
the circuit (100) further comprises second selection means (130) which are adapted to remove at least a part of the generated sub-harmonics (231) from a signal generated by the harmonic generator (120), and
the adding means (140) are adapted to add the output signal of the second selection means (130) to the audio signal.

2. A circuit (100) as claimed in claim 1, characterized in that the frequency bands to be selected by the first and second selection means are adjustable.

3. A circuit (100) as claimed in claim 1, in which an output of the adding means (140) is connected to a loudspeaker, characterized in that the second selection means (130) are further adapted to remove low frequencies, which cannot be reproduced by the loudspeaker, from an output signal of the harmonic generator (120).

4. A circuit as claimed in claim 1, characterized in that the second selection means (130) comprise a filter which substantially does not pass at least a first frequency band and passes a second frequency band at a first level and a third frequency band at a second level.

5. A circuit as claimed in claim 1, characterized in that the circuit further comprises amplifier means which are adapted to amplify the output signal of the second selection means before said output signal is added, during use, to the audio signal.

6. A circuit as claimed in claim 1, characterized in that the circuit comprises delay means (150) which are adapted to delay the audio signal before said audio signal is added, in use, to the output signal of the selection means (130).

7. A circuit as claimed in claim 1, characterized in that the first selection means (110) and the second selection means (130) are linear phase filters.

8. An apparatus (400) for reproducing audio signals, the apparatus comprising a circuit (405) as claimed in claim 1.

9. A method for processing an audio signal, the method comprising the steps of:
selecting a frequency band (111) of the audio signal,
generating a signal comprising sub-harmonics (231) of frequencies (211) in the selected frequency band (111) and comprising higher harmonics (232) of the generated sub-harmonics (231),
characterized in that the method comprises the further steps of:
removing at least a part of the sub-harmonics (231) from the generated signal, and
adding the generated signal, from which at least a part of the sub-harmonics (231) has been removed, to the audio signal.

10. A record carrier (510) comprising instructions which can be carried out by a processor, characterized in that the instructions enable the processor to perform the method as claimed in claim 9.
